(19) United States
(12) Patent Application Publication
(10) Pub. No.: US 2020/0401036 A1
(43) Pub. Date: Dec. 24, 2020

(54) Mask and Method for preparing a Mask

(71) Applicants: BEIJING BOE DISPLAY TECHNOLOGY CO., LTD., Beijing (CN); BOE Technology Group Co., Ltd., Beijing (CN)

(72) Inventors: Jinchao Bai, Beijing (CN); Huibin Guo, Beijing (CN); Mingxuan LIU, Beijing (CN); Xiao Han, Beijing (CN); Xiangqian Ding, Beijing (CN); Yongzhi Song, Beijing (CN)

(21) Appl. No.: 16/959,190

(22) PCT Filed: Aug. 28, 2018
(86) PCT No.: PCT/CN2018/102716

§ 371 Date: Jun. 30, 2020

(30) Foreign Application Priority Data
Jan. 17, 2018 (CN) 201810043444.1

(51) Int. Cl. G03F 1/26

(52) U.S. Cl. CPC G03F 1/26

(57) ABSTRACT

A mask and a method for preparing the mask are provided in embodiments of the present disclosure. The mask includes: a substrate; and at least one first photo-resistance structure and at least one second photo-resistance structure on the substrate; the first photo-resistance structure includes a first light shielding film layer and an optical filter film layer, and the optical filter film layer includes a first optical filter portion whose orthographic projection on the substrate is located out of an edge of an orthographic projection of the first light shielding film layer on the substrate and adjoins the edge of the orthographic projection of the first light shielding film layer on the substrate; and the second photo-resistance structure merely includes a second light shielding film layer.

### CROSS-REFERENCE TO RELATED APPLICATION

This application is a Section 371 National Stage Application of International Application No. PCT/CN2018/102716, filed on Aug. 28, 2018, which published as WO 2019/140914, entitled “Mask and Method for preparing a Mask”, and claims priority to Chinese Patent Application No. 201810043444.1 filed on Jan. 17, 2018, the disclosures of which are incorporated herein by reference in their entireties.

### TECHNICAL FIELD

Embodiments of the present disclosure relates to a field of display technology, and in particular, to a mask and a method for preparing a mask.

### BACKGROUND

In display panel industry, a mask is typically used to form patterns on an array substrate and the like in producing the latter. Therefore, selection of suitable mask may simplify the process of producing the array substrate so as to save costs for manufacturing.

In relevant art, upon patterning the array substrate, it is desired to form patterns that may be formed at same condition(s), for example by merely one patterning process, i.e., the patterning is implemented at a same exposure intensity with one mask. However, when the mask is used to form patterns, many patterns to be formed have different requirements on respective quantities of exposure, thus requiring at least two masks to implement patterning so as to form the array substrate having patterns which are the same as preset. In a condition that two masks are for example needed to form a plurality of patterns which are to be formed and have different requirements on respective quantities of exposure (or exposure amounts hereinafter), then, provided that two patterns which are to be formed and have different requirements on respective quantities of exposure may be prepared with merely one masks, there may be a condition that one of the two patterns is overexposed while other is underexposed.

### SUMMARY

The embodiments of the present disclosure have been made to overcome or alleviate at least one aspect of the above mentioned defects and/or deficiencies in the relevant art, by providing a mask and a method for preparing a mask.

In order to achieve above purposes, following technical solutions are mainly provided in exemplary embodiments of the disclosure.

Therefore, in an aspect of embodiments of the present disclosure, there is provided mask comprising:

a substrate; and

at least one first photo-resistance structure and at least one second photo-resistance structure on the substrate;

wherein the first photo-resistance structure comprises a first light shielding film layer and an optical filter film layer, and the optical filter film layer comprises a first optical filter portion whose orthographic projection on the substrate is located out of an edge of an orthographic projection of the first light shielding film layer on the substrate and adjoins the edge of the orthographic projection of the first light shielding film layer on the substrate; and

the second photo-resistance structure comprises a second light shielding film layer.

In accordance with embodiments of the present disclosure, the first optical filter portion is arranged to adjoin the first light shielding film layer in a thickness direction of the first light shielding film layer or in a direction perpendicular to the thickness direction of the first light shielding film layer.

In accordance with embodiments of the present disclosure, the orthographic projection of the first light shielding film layer on the substrate is surrounded by or contained within the orthographic projection of the optical filter film layer on the substrate.

In accordance with embodiments of the present disclosure, the optical filter film layer is located between the substrate and the first light shielding film layer.

In accordance with embodiments of the present disclosure, the optical filter film layer further comprises:

a second optical filter portion on a side of the first light shielding film layer which side faces away from the substrate.

In accordance with embodiments of the present disclosure, the first photo-resistance structure is configured to form metal lines therein and the second photo-resistance structure is configured to form channels therein.

In accordance with embodiments of the present disclosure, both the material by which the first light shielding film layer is formed and the material by which the second light shielding film layer is formed comprise a material composition of chromium molybdenum oxide.

In another aspect of embodiments of the present disclosure, there is provided a method for preparing a mask, the method comprising:

forming a pattern of a first photo-resistance structure and a pattern of a second photo-resistance structure on a substrate;

wherein the first photo-resistance structure comprises a first light shielding film layer and an optical filter film layer, the optical filter film layer comprises a first optical filter portion whose orthographic projection on the substrate is located out of an edge of an orthographic projection of the first light shielding film layer on the substrate and adjoins the edge of the orthographic projection of the first light shielding film layer on the substrate; and

the second photo-resistance structure comprises a second light shielding film layer.

In accordance with embodiments of the present disclosure, the forming the pattern of the first photo-resistance structure and the pattern of the second photo-resistance structure on the substrate comprises:

forming a pattern of the first light shielding film layer and a pattern of the second light shielding film layer on the substrate by using one patterning process; and

forming a pattern of the optical filter film layer on the substrate by using another patterning process,

wherein a pattern of the first optical filter portion of the optical filter film layer adjoins the first light shielding film layer in thickness direction of the first light shielding film layer or in a direction perpendicular to the thickness direction of the first light shielding film layer.

In accordance with embodiments of the present disclosure, the orthographic projection of the first light shielding film layer on the substrate is surrounded by or contained within the orthographic projection of the optical filter film layer on the substrate.

In accordance with embodiments of the present disclosure, the forming the pattern of the first photo-resistance structure and the pattern of the second photo-resistance structure on the substrate comprises:

forming a pattern of the first light shielding film layer and a pattern of the second light shielding film layer on the substrate by using one patterning process; and

forming a pattern of the optical filter film layer on a side of the first light shielding film layer which side faces away from the substrate by using another patterning process,

wherein the pattern of the optical filter film layer further comprises:

a second optical filter portion covering a side of the first light shielding film layer which side faces away from the substrate.

In accordance with embodiments of the present disclosure, the forming the pattern of the first photo-resistance structure and the pattern of the second photo-resistance structure on the substrate comprises:

forming a pattern of the optical filter film layer on the substrate by using one patterning process; and

forming a pattern of the first light shielding film layer on a side of the optical filter film layer which side faces away from the substrate, while forming a pattern of the second light shielding film layer on a portion of the substrate which portion is not covered by the optical filter film layer, by using another patterning process.

In accordance with embodiments of the present disclosure, the first photo-resistance structure is configured to form metal lines therein, and the second photo-resistance structure is configured to form channels therein.

In accordance with embodiments of the present disclosure, both the material by which the first light shielding film layer is formed and the material by which the second light shielding film layer is formed comprise a material composition of chromium molybdenum oxide.

### BRIEF DESCRIPTION OF THE DRAWINGS

The above and other features and advantages of embodiments of the present disclosure will become apparent from the following detailed depiction of the present disclosure, with reference to the accompanying drawings, facilitating obtaining a comprehensive understanding of the present disclosure.

FIG. 1 is a schematic view showing a structure of a mask provided by the relevant art;

FIG. 2 is a schematic view showing a structure of a mask according to an embodiment in an aspect of the present disclosure;

FIG. 3 is a schematic view showing a structure of a mask according to another embodiment in an aspect of the present disclosure.

FIG. 4 is a schematic view showing a structure of a mask according to a still another embodiment in an aspect of the present disclosure.

FIG. 5a and FIG. 5b are schematic views showing structures formed by a method for preparing the mask according to an embodiment in another aspect of the present disclosure.

FIG. 6a and FIG. 6b are schematic views showing structures formed by a method for preparing the mask according to another embodiment in another aspect of the present disclosure.

FIG. 7a and FIG. 7b are schematic views showing structures formed by a method for preparing the mask according to still another embodiment in another aspect of the present disclosure.

### DETAILED DESCRIPTION OF EMBODIMENTS

The technical solutions of the present disclosure will be further described below with reference to the drawings and the embodiments of the present disclosure. Throughout the description, same or similar reference numerals represent same or similar components. The following description on embodiments of the present disclosure with reference to the drawings is intended to explain the generic inventive concept of the present disclosure instead of limiting the present disclosure.

In addition, in the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

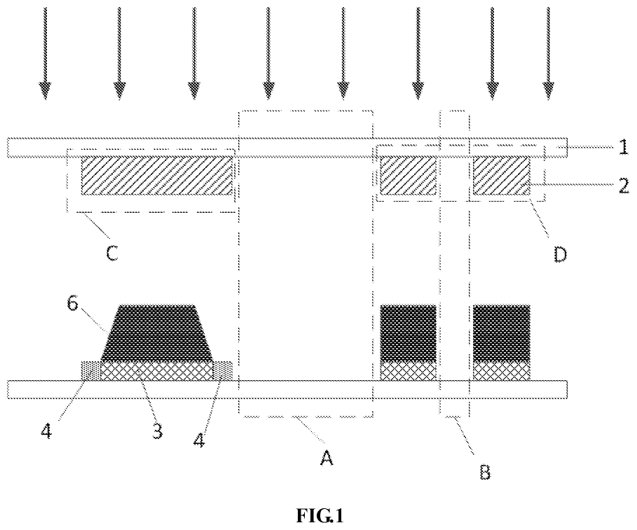

The mask in the relevant art, as shown in FIG. 1, comprises a pattern of a light shielding layer 2 on a substrate 1. There are two structures on the substrate 1 which are to be used for shielding light in exposure process, i.e., comprising a first photo-resistance structure C and a second photo-resistance structure D as illustrated respectively. Two regions to be exposed to light are provided respectively on an opposite substrate, for example an array substrate arranged opposite to the substrate 1, and are aligned with these two structures respectively along a direction perpendicular to the substrate 1. The two regions are a first exposure region A to be exposed by the first photo-resistance structure C as illustrated and a second exposure region B to be exposed by the second photo-resistance structure D as illustrated. And the second exposure region B is for example configured to be exposed to form a channel region therein, while the first exposure region A is for example configured to be exposed to form a region in which metal lines are provided. The first exposure region A and the second exposure region Bare for example together exposed to light once (for example using a same mask). In contrast to the first exposure region A, the second exposure region B that is aligned with the second photo-resistance structure D is set to have a smaller width. Then, in order to form a relatively narrower channel in the second exposure region B, a relative large exposure amount is required therein correspondingly. In contrast, the first exposure region A that is aligned with the first photo-resistance structure C is set to have a larger width. Then the above relative large exposure amount may result in an overexposed region 4 generated in the region where metal lines are provided in the first exposure region A, and the pattern of the exposed photoresist 6 is less than a preset value such that a practical width of the resultant metal line pattern 3 is less than a preset width of a metal line pattern, i.e., the preset width of the metal line pattern is a sum of the width of the resultant metal line pattern 3 and the width of the overexposed region 4.

Except the above condition, for example through holes with different depths are required to be formed in patterning the array substrate. The through holes with different depths have different requirements on the exposure. Thus, it may also cause issues that the same mask may not be used in a preparing process.

Certainly, in addition to above two conditions, there are other issues that different requirements on exposure amount cause the patterns to be formed may not be produced by merely one mask. These details will be omitted here, without being repeated any more.

Thus, it is a technical problem to be solved for those skilled in the art how to prepare the pattern to be formed at different exposure amounts with single mask so as to simplify the producing process. In accordance with a general inventive concept of embodiments of the present disclosure, a mask and a method for preparing the mask are provided, intending to solve the technical problem that two patterns to be formed having different requirements on the exposure amounts in the relevant art cannot be produced by one mask.

In view of above problem, in an aspect of the embodiments of the present disclosure, a mask is provided. Specific implementations for the mask and the method for preparing the according to the embodiments of the present disclosure are described with reference to drawings and embodiments where the metal line and the channel are formed by one mask.

Respective dimension (e.g., thickness) and shape of film layers and components in the drawings are merely intended to exemplarily illustrate the contents of embodiments of the disclosure, rather than to demonstrate the practical dimension or proportion of film layers and components of the mask in the embodiment of the present disclosure.

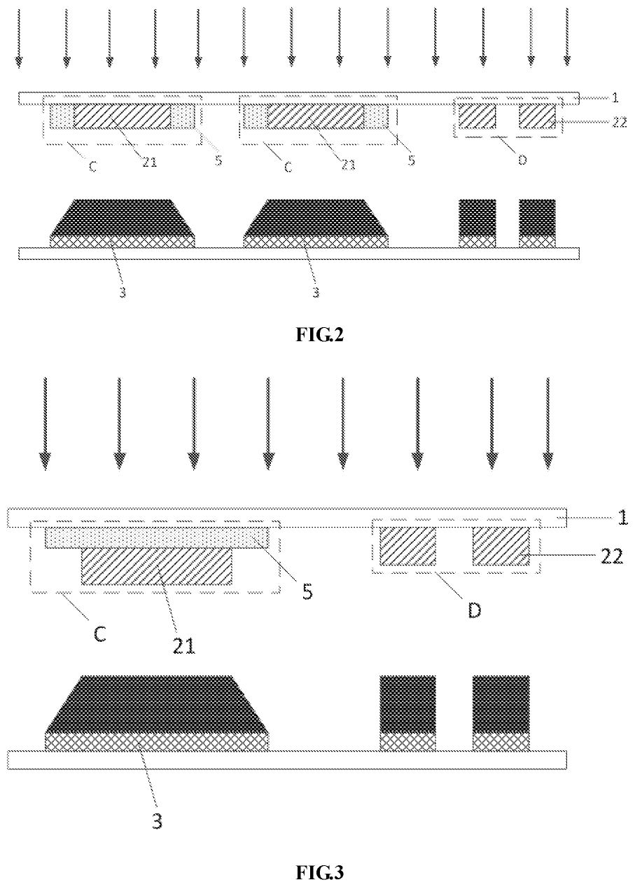

With respect to above questions, a mask is provided in embodiments of the present disclosure. As shown in FIG. 2 to FIG. 4, the mask comprises: a substrate 1; and at least a first photo-resistance structure C and at least a second photo-resistance structure D on the substrate 1.

The first photo-resistance structure C comprises a first light shielding film layer 21 and an optical filter film layer 5. The optical filter film layer 5 comprises a first optical filter portion. An orthographic projection of the first optical filter portion on the substrate is located outside and abuts against (i.e., adjoins) edges of an orthographic projection of the first light shielding film layer on the substrate; for example, the optical filter film layer 5 is arranged to abut against closely at least one side of the first light shielding film layer 21, and the optical filter film layer 5 extends at least in a direction perpendicular to a thickness direction of the first light shielding film layer 21 towards two opposite sides of the first light shielding film layer 21 and beyond the first light shielding film layer 21. And the second photo-resistance structure D merely comprises a second light shielding film layer 22.

The above mask according to the embodiments of the present disclosure comprises: the substrate; and at least a first photo-resistance structure and at least a second photo-resistance structure on the substrate. The first photo-resistance structure comprises a first light shielding film layer and an optical filter film layer. The optical filter film layer is arranged to abut against closely at least one side of the first light shielding film layer, for example, is arranged to abut against closely two opposite sides of the first light shielding film layer, or is arranged between the substrate and the first light shielding film layer by abutting against closely the substrate and the first light shielding film layer. And the optical filter film layer extends in a direction perpendicular to the thickness direction of the first light shielding film layer 21 towards two opposite sides beyond the first light shielding film layer 21 and beyond the first light shielding film layer. The second photo-resistance structure only comprises a second light shielding film layer. By providing the optical filter film layer on at least one side of the first light shielding film layer by abutting thereon closely, and providing the optical filter film layer to extend towards two opposite sides of the first light shielding film layer and beyond the first light shielding film layer in the direction perpendicular to the thickness direction of the first light shielding film layer, the quantity of exposure of the at least one side of the light shielding layer may be reduced to prevent the pattern formed by the first photo-resistance structure from being overexposed. As such, the patterns to be formed with different requirements on quantity of exposure may for example be formed with one mask having both of the first photo-resistance structure and the second photo-resistance structure, so as to simplify the preparing process.

In specific implementation, in the above mask according to the embodiments of the present disclosure, the exposure process is performed by guiding an incident light into the first photo-resistance structure and the second photo-resistance structure from a side of the substrate which side faces away from both the first photo-resistance structure and the second photo-resistance structure. The first photo-resistance structure and the second photo-resistance structure are used to shield light in exposure process, so as to form structures of different patterns on an opposite substrate (e.g., an array substrate) which is provided opposite to the substrate and located downstream the substrate in an optical path of the incident light. In other words, the first photo-resistance structure is configured to shield light in the exposure process to form a pattern (for example, to form an region where the metal lines are provided) on the array substrate while the second photo-resistance structure is configured to shield light in the exposure process to form another pattern (for example, to form a channel region) on the array substrate. The pattern formed by the first photo-resistance structure needs the quantity of exposure which is less than the quantity of exposure required for the pattern formed by the second photo-resistance structure.

It should be noted that, in the above mask according to the embodiments of the present disclosure, for example, the optical filter film layer is arranged to abut against closely at least one side of the first light shielding film layer and to extend beyond the first light shielding film layer towards two opposite sides of the first light shielding film lay in the direction perpendicular to the thickness direction of the first light shielding film layer. It means that, in a condition that the pattern formed by the first photo-resistance structure is the metal line, the optical filter film layer is provided in the same layer as the first light shielding film layer and is arranged to abut against closely at least one side of the first light shielding film layer and to extend beyond the first light shielding film layer towards two opposite sides of the first light shielding film layer in a direction in which the metal line extends, such that no overexposure will occur at a position where the metal line is formed actually and thus the width of the metal line formed actually tends to be equal to the preset width of the metal line. And in a condition that the pattern formed by exposure with the first photo-resistance structure is a closed pattern having a certain shape, the optical filter film layer is for example arranged to abut against closely a peripheral edge of the first light shielding film layer in the direction perpendicular to the thickness direction of the first light shielding film layer, so as to decrease the intensity of exposure on the structure to be patterned on the array substrate, such that the dimension of the pattern formed actually on the array substrate tends to be equal to the preset dimension of the pattern. The specific positions of the optical filter film layer with respect to the first light shielding film layer may be determined by the pattern produced actually and are not specifically limited here.

It should be noted that the optical filter film layer refers to a film that may reduce luminous flux of light passing therethrough. The thickness of the optical filter film layer may affect the intensity of the light passing therethrough to some extent; in particular, typically, the capability of the optical filter film layer increases as the thickness of the optical filter film layer increases, that is, the luminous flux of light passing through the optical filter film layer is reduced as the thickness of the optical filter film layer increases. Thus, in specific implementation, the thickness of the optical filter film layer may be selected as per practical requirements and is not specifically limited here.

In an exemplary embodiment, in the above mask according to the embodiments of the present disclosure, as shown in FIG. 2, the optical filter film layer 5 is provided in the same layer as the first light shielding film layer 21, and is arranged to abut against closely two opposite sides of the first light shielding film layer 21 in the direction perpendicular to the thickness direction of the first light shielding film layer and extends towards the two opposite sides beyond the first light shielding film layer in the direction perpendicular to the thickness direction of the first light shielding film layer. In such a condition, for example, an orthographic projection of the first light shielding film layer 21 on the substrate 1 is surrounded by an orthographic projection of the optical filter film layer 5 on the substrate 1, and the orthographic projection of the first light shielding film layer 21 on the substrate 1 and the orthographic projection of the optical filter film layer 5 on the substrate 1 do not overlap with each other. Then, the specific producing process of the mask comprises following steps in sequence: above all, forming the first light shielding film layer 21 and the second light shielding film layer 22 on the substrate 1; and then forming the optical filter film layer 5 on two opposite sides of the first light shielding film layer 21 in the direction perpendicular to the thickness direction of the first light shielding film layer, or further forming the optical filter film layer 5 at a position abut against closely the peripheral edge of the first light shielding film layer 21.

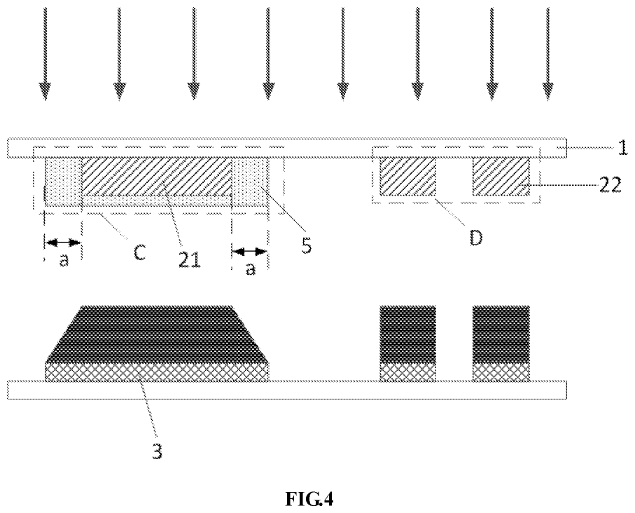

In an alternative exemplary embodiment, in the above mask according to the embodiment of the present disclosure, as shown in FIG. 3 and FIG. 4, the orthographic projection of the first light shielding film layer 21 on the substrate 1 is in entirety located in the orthographic projection of the optical filter film layer 5 on the substrate 1, and the optical filter film layer extends outwardly beyond the first light shielding film layer in the direction perpendicular to the thickness direction of the first light shielding film layer.

In other words, in the above mask according to the embodiment of the present disclosure, a range of the orthographic projection of the optical filter film layer on the substrate covers a range of the orthographic projection of the first light shielding film layer, thereby, the dimension of the optical filter film layer is larger than the dimension of the first light shielding film layer, i.e., the dimension of the optical filter film layer on the substrate is larger than the dimension of the orthographic projection of the first light shielding film layer on the substrate. Therefore, a portion of the optical filter film layer extending beyond the first light shielding film layer may effectively reduce the amount of light transmitted therethrough, so as to alleviate overexposure of the patterns to be formed, and to cause the orthographic projection of the first light shielding film layer on the substrate falls within the orthographic projection of the optical filter film layer on the substrate, thus reducing the difficulty in the patterning process upon forming the optical filter film layer.

In a further exemplary embodiment, in the above mask according to the embodiment of the present disclosure, as shown in FIG. 3, the optical filter film layer 5 is for example located between the substrate 1 and the first light shielding film layer 21, and the optical filter film layer 5 extends outwardly beyond the first light shielding film layer in the direction perpendicular to the thickness direction of the first light shielding film layer.

By way of example, in the above mask according to the embodiment shown in FIG. 3, in a condition that the orthographic projection of the first light shielding film layer 21 on the substrate 1 falls within the orthographic projection of the optical filter film layer 5 on the substrate 1, the optical filter film layer is for example provided between the substrate and the first light shielding film layer, then the process for preparing the mask may specifically comprise following steps in sequence: above all, forming the optical filter film layer 5 on the substrate 1, and then continuing the patterning process in the thickness direction to form the first light shielding film layer 21 and the second light shielding film layer 22 (for example, they may be formed in a same process or in different processes). The first light shielding film layer 21 is formed on the optical filter film layer 5, while the second light shielding film layer 22 is formed directly on the portion of the substrate 1 which portion is not covered by the optical filter film layer 5.

And for example, the optical filter film layer may further comprise: a second optical filter portion on a side of the first light shielding film layer which side faces away from the substrate. More specifically, further defined conditions are specifically set forth as below.

In another further embodiment, in the above mask according to the embodiment of the present disclosure, as shown in FIG. 4, the optical filter film layer 5 at least comprises a first portion of the optical filter film layer on the side of the first light shielding film layer 21 which side faces away from the substrate 1. In addition, the optical filter film layer 5 may for example further comprise a second portion of the optical filter film layer which abuts against closely two opposite sides of the first light shielding film layer in the direction perpendicular to the thickness direction of the first light shielding film layer, and the optical filter film layer extends outwardly beyond the first light shielding film layer in the direction perpendicular to the thickness direction of the first light shielding film layer.

In yet another further embodiment, in the above mask according to the embodiment of the present disclosure, as shown in FIG. 4, the optical filter film layer 5 at least comprises a first portion of the optical filter film layer on a side of the first light shielding film layer 21 which side faces away from the substrate 1. In addition, the optical filter film layer 5 may for example further comprise a second portion of the optical filter film layer which abuts against closely the peripheral edge of the first light shielding film layer (i.e., surrounds the first light shielding film layer closely), and the optical filter film layer extends outwardly beyond the first light shielding film layer in a radial direction of the peripheral edge of the first light shielding film layer.

For example, in the above mask according to the embodiment shown in FIG. 4, in a condition that the orthographic projection of the first light shielding film layer on the substrate falls within the orthographic projection of the optical filter film layer on the substrate, the optical filter is for example at least provided on the side of the first light shielding film layer which side faces away from the substrate, then the specific preparing process of the mask comprises following steps in sequence: above all, forming the first light shielding film layer and the second light shielding film layer on the substrate, and then forming the optical filter film layer (for example the first portion of the optical filter film layer) on the first light shielding film layer; and for example providing additionally the second portion of the optical filter film layer on two opposite sides or the peripheral edge of the first light shielding film layer.

For example, in the mask according to the above embodiment as shown, the first photo-resistance structure is configured to form the metal line and the second photo-resistance structure is configured to form the channel therein. The two opposite sides are two sides in a direction parallel to the direction along which the metal line extends.

By way of example, in practical implementation, in the above mask according to the embodiment of the present disclosure, as shown in FIG. 4, the orthographic projection of the optical filter film layer 5 on the substrate 1 and the orthographic projection of the first light shielding film layer 21 on the substrate 1 do not completely overlap with each other, i.e., there exists an non-overlapped portion of the optical filter film layer which is the second portion of the optical filter film layer extending beyond the first light shielding film layer and has a width a of 0.1 to 2 micrometers. In a condition of such a size, the optical filter film layer for example filters out appropriate quantity of light effectively such that the pattern formed practically formed will not be overexposed and will not have excessively large width due to the size of the optical filter film layer.

For example, in the above mask according to the embodiment of the present disclosure, both the material by which the first light shielding film layer is formed and the material by which the second light shielding film layer is formed comprise a material composition of chromium molybdenum oxide.

In particular, in the above mask according to the embodiment of the present disclosure, in a condition that the second photo-resistance structure in the mask is used to form the channel and the first photo-resistance structure is used to form the metal line, the mask is for example a Phase Shift Mask (abbreviated as PSM). At that time, each of the first light shielding film layer and the second light shielding film layer is a film layer which changes phase of polarization or vibration of light by 180°. Certainly, any other material that may function as mask in specific implementation may be used. Specific type of the mask and specific material(s) of the first light shielding film layer and the second light shielding film layer may be selected as required in specific implementation, without being specifically limited herein.

Based on a same inventive concept, in embodiments of the present disclosure, there is also provided a method for preparing a mask, the method comprising:

forming a pattern of a first photo-resistance structure and a pattern of a second photo-resistance structure on a substrate.

The first photo-resistance structure comprises a first light shielding film layer and an optical filter film layer; and the optical filter film layer comprising a first optical filter portion whose orthographic projection on the substrate is located out of an edge of an orthographic projection of the first light shielding film layer on the substrate and adjoins the edge of the orthographic projection of the first light shielding film layer on the substrate. For example, the optical filter film layer abuts against closely the at least one side of the first light shielding film layer and the optical filter film layer extends towards two opposite sides of the first light shielding film layer and beyond the first light shielding film layer in the direction perpendicular to the thickness direction of the first light shielding film layer; the second photo-resistance structure comprises a second light shielding film layer.

For example, the step of forming the pattern of the first photo-resistance structure and the pattern of the second photo-resistance structure on the substrate comprises:

forming a pattern of the first light shielding film layer and a pattern of the second light shielding film layer on the substrate by using one patterning process; and

forming a pattern of the optical filter film layer on the substrate by using another patterning process.

A pattern of the first optical filter portion of the optical filter film layer adjoins the first light shielding film layer in the thickness direction of the first light shielding film layer or in a direction perpendicular to the thickness direction of the first light shielding film layer. Specific embodiments are set forth in detail hereinafter.

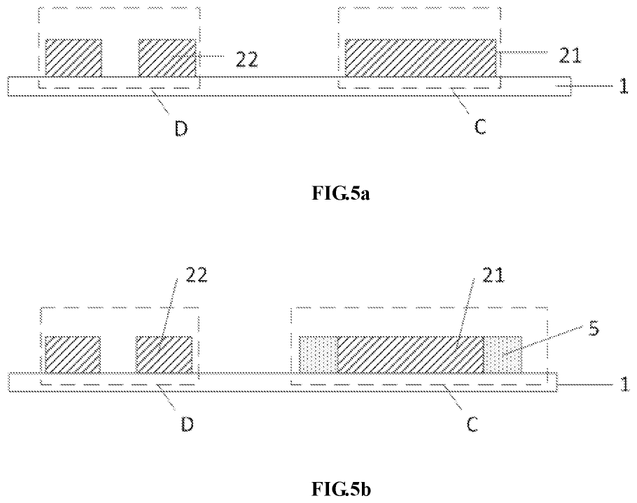

For example, in the above method for preparing the mask according to the embodiment of the present disclosure, as shown in FIG. 5a and FIG. 5b, the step of forming the pattern of the first photo-resistance structure and the pattern of the second photo-resistance structure on the substrate, that is, forming the pattern of the first light shielding film layer 21 and the pattern of the second light shielding film layer 22 and the pattern of the optical filter film layer 5 that abuts against closely two opposite sides of the first light shielding film layer 21 in the direction perpendicular to the thickness direction of the first light shielding film layer 21 on the substrate 1, specifically comprises:

forming the pattern of the first light shielding film layer 21 and the pattern of the second light shielding film layer 22 on the substrate 1 by using one patterning process; and

forming a pattern of the optical filter film layer 5 only abutting against closely two opposite sides of the first light shielding film layer 21 in the direction perpendicular to the thickness direction of the first light shielding film layer 21 by using another patterning process. The optical filter film layer 5 is formed to extend towards two opposite sides of the first light shielding film layer and beyond the first light shielding film layer in a direction parallel to the substrate (i.e., in the direction perpendicular to the thickness direction of the first light shielding film layer 21).

Accordingly, the mask prepared by the method for preparing the mask as illustrated in FIG. 5a and FIG. 5b is for example shown in FIG. 2.

For example, the optical filter film layer may be formed to comprise: a second optical filter portion on the side of the first light shielding film layer which side faces away from the substrate. More specifically, further defined conditions are specifically set forth as below.

It should be noted that in the above method for preparing the mask according to the embodiment of the present disclosure, the pattern of the optical filter film layer may alternatively for example be formed above all, and then the pattern of the first light shielding film layer and the pattern of the second light shielding film layer are formed. The optical filter film layer is formed to extend towards two opposite sides of the first light shielding film layer and beyond the first light shielding film layer in the direction perpendicular to the thickness direction of the first light shielding film layer. In the preparing process in practice, it may be selected as per practical requirements in use, without being specifically limited herein.

It should be noted that, in the above method for preparing the mask according to the embodiment of the present disclosure, for example, the pattern of the first light shielding film layer 21 and the pattern of the second light shielding film layer 22 may further be formed, above all, by using one patterning process, and then the pattern of the optical filter film layer 5 only abutting against closely the peripheral edge of the first light shielding film layer 21 in the direction perpendicular to the thickness direction of the first light shielding film layer 21 by using another patterning process. The optical filter film layer 5 is formed to extend outwardly beyond the first light shielding film layer in the radial direction of the peripheral edge of the first light shielding film layer 21. In the preparing process in practice, it may be selected as per practical requirements in use, without being specifically limited herein.

It should be noted that, in the above method for preparing the mask according to the embodiment of the present disclosure, the pattern of the optical filter film layer in form of a hollow closed pattern may further for example be formed above all, and then the pattern of the second light shielding film layer 5 as well as the pattern of the first light shielding film layer surrounded within and defined by the pattern of the optical filter film layer are formed. The optical filter film layer is formed to extend outwardly beyond the first light shielding film layer in the radial direction of the peripheral edge of the first light shielding film layer. In the preparing process in practice, it may be selected as per practical requirements in use, without being specifically limited herein.

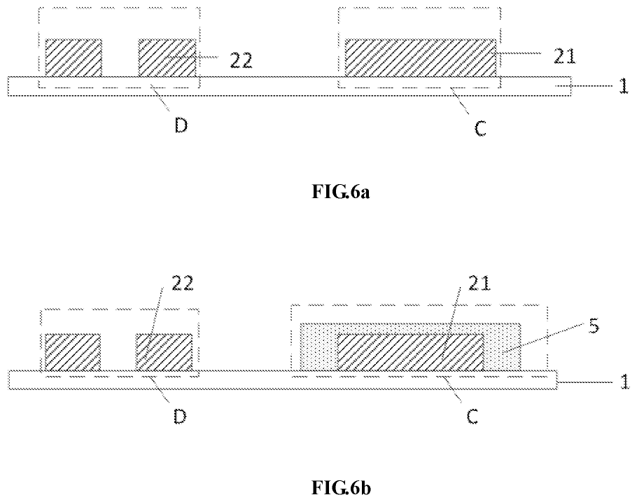

For example, firstly, in the above method for preparing the mask according to the embodiment of the present disclosure, as shown in FIG. 6a and FIG. 6b, the step of forming the pattern of the first photo-resistance structure and the pattern of the second photo-resistance structure on the substrate, that is, forming the pattern of the first light shielding film layer 21, and the pattern of the second light shielding film layer 22, as well as the pattern of the optical filter film layer 5 that covers the first light shielding film layer 21 in the thickness direction of the first light shielding film layer 21 and abuts against closely two opposite sides of the first light shielding film layer 21 in the direction perpendicular to the thickness direction of the first light shielding film layer 21, on the substrate 1, specifically comprises:

forming the pattern of the first light shielding film layer 21 and the pattern of the second light shielding film layer 22 on the substrate 1 by using one patterning process; and

forming a pattern of the optical filter film layer 5 on the side of the first light shielding film layer 21 which side faces away from the substrate 1 by using another patterning process.

The pattern of the optical filter film layer 5 further comprises: a first portion of the optical filter film layer 5 on the side of the first light shielding film layer 21 which side faces away from the substrate 1, and a second portion of the optical filter film layer 5 which abuts against closely two opposite sides of the first light shielding film layer 21 in the direction perpendicular to the thickness direction of the first light shielding film layer 21. The optical filter film layer 5 is formed to extend outwardly beyond the first light shielding film layer 21 in the direction perpendicular to the thickness direction of the first light shielding film layer 21.

Correspondingly, the mask produced by the method for preparing the mask as illustrated in FIG. 6a and FIG. 6b is for example shown in FIG. 4.

For example, secondly, in an alternative embodiment, the step of forming the pattern of the first photo-resistance structure and the pattern of the second photo-resistance structure on the substrate, that is, forming the pattern of the first light shielding film layer, and the pattern of the second light shielding film layer, as well as the pattern of the optical filter film layer that covers the first light shielding film layer in the thickness direction of the first light shielding film layer and abuts against closely the peripheral edge of the first light shielding film layer (i.e., closely surrounds the first light shielding film layer), on the substrate, specifically comprises:

forming the pattern of the first light shielding film layer 21 and the pattern of the second light shielding film layer 22 on the substrate 1 by using one patterning process; and

forming a pattern of the optical filter film layer 5 on the side of the first light shielding film layer which side faces away from the substrate 1 by using another patterning process.

The pattern of the optical filter film layer further comprises: a first portion of the optical filter film layer covering the side of the first light shielding film layer which side faces away from the substrate, and a second portion of the optical filter film layer which is located to abut against closely the peripheral edge of the first light shielding film layer (i.e., closely surrounds the first light shielding film layer). The optical filter film layer is formed that the second portion thereof extends outwardly beyond the first light shielding film layer in the radial direction of the peripheral edge of the first light shielding film layer.

In specific implementation, in the above method for preparing the mask according to the embodiment of the present disclosure, the pattern of the first light shielding film layer and the pattern of the second light shielding film layer are formed above all on the substrate, and then the pattern of the optical filter film layer is formed on the side of the first light shielding film layer which side faces away from the substrate. It is intended to set forth that, the optical filter film layer is formed above the first light shielding film layer and at least covers the side of the first light shielding film layer which side faces away from the substrate, and the orthographic projection of the first light shielding film layer on the substrate falls within the orthographic projection of the optical filter film layer on the substrate, that is, the orthographic projection of the optical filter film layer on the substrate covers the orthographic projection of the first light shielding film layer on the substrate and the border of the orthographic projection of the optical filter film layer on the substrate is not overlapped with the border of the orthographic projection of the first light shielding film layer on the substrate. And the second portion of the optical filter film layer extends beyond the first light shielding film layer, facilitating effective reduction of the amount of light transmitted therethrough, so as to alleviate overexposure of the patterns to be formed.

In summary, in other words, the embodiments as shown in FIG. 6a to FIG. 6b and extensible embodiments associated therewith may be summarized hereinafter.

The step of forming the pattern of the first photo-resistance structure and the pattern of the second photo-resistance structure on the substrate comprises:

forming a pattern of the first light shielding film layer and a pattern of the second light shielding film layer on the substrate by using one patterning process; and

forming a pattern of the optical filter film layer on the side of the first light shielding film layer which side faces away from the substrate by using another patterning process, the pattern of the optical filter film layer further comprising a second optical filter portion covering the side of the first light shielding film layer which side faces away from the substrate.

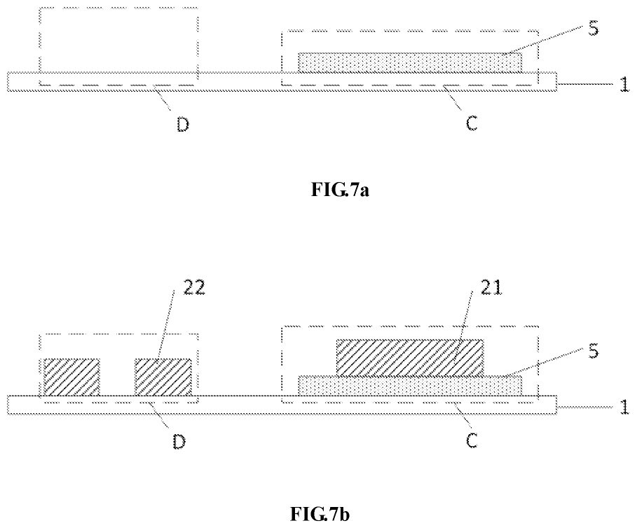

In additional embodiments, for example, in the above method for preparing the mask according to the embodiment of the present disclosure, as shown in FIG. 7a and FIG. 7b, the step of forming the pattern of the first photo-resistance structure and the pattern of the second photo-resistance structure on the substrate, that is, forming the pattern of the first light shielding film layer 21 and the pattern of the second light shielding film layer 22 on the substrate 1 as well as the pattern of the optical filter film layer 5 located between the substrate 1 and the first light shielding film layer 21, specifically comprises:

forming the pattern of the optical filter film layer 5 on the substrate 1 by using one patterning process; and

forming a pattern of the first light shielding film layer 21 on the side of the first light shielding film layer 21 which side faces away from the substrate 1 by using another patterning process, while forming a pattern of the second light shielding film layer 22 on the portion of the substrate 1 which is not covered by the optical filter film layer 5 by using another patterning process. The optical filter film layer 5 is formed to extend towards two opposite sides of the first light shielding film layer 21 and beyond the first light shielding film layer 21 in the direction perpendicular to the thickness direction of the first light shielding film layer 21.

Correspondingly, the mask produced by the method for preparing the mask as illustrated in FIG. 7a and FIG. 7b is for example shown in FIG. 3.

In specific implementation, in the above method for preparing the mask according to the embodiment of the present disclosure, the pattern of the optical filter film layer is formed above all on the substrate, and then the pattern of the first light shielding film layer and the pattern of the second light shielding film layer are formed on the side of the first light shielding film layer which side faces away from the substrate. It is intended to set forth that, the optical filter film layer is formed between the first light shielding film layer and the substrate, and the orthographic projection of the first light shielding film layer on the substrate falls within the orthographic projection of the optical filter film layer on the substrate, i.e., the orthographic projection of the optical filter film layer on the substrate covers the orthographic projection of the first light shielding film layer on the substrate and the border of the orthographic projection of the optical filter film layer on the substrate does not overlaps with the border of the orthographic projection of the first light shielding film layer on the substrate. And the portion of the optical filter film layer extends beyond the first light shielding film layer, facilitating effective reduction of the amount of light transmitted therethrough, so as to alleviate overexposure of the patterns to be formed.

In summary, in other words, the embodiments as illustrated in FIG. 5a to FIG. 5b and embodiments as illustrated FIG. 7a to FIG. 7b may be summarized hereinafter.

The step of forming the pattern of the first photo-resistance structure and the pattern of the second photo-resistance structure on the substrate comprises:

forming the pattern of the first light shielding film layer and the pattern of the second light shielding film layer on the substrate by using one patterning process; and

forming the pattern of the optical filter film layer on the substrate by using another patterning process, the pattern of the first optical filter portion of the optical filter film layer adjoining the first light shielding film layer in thickness direction of the first light shielding film layer or in the direction perpendicular to the thickness direction of the first light shielding film layer.

It should be noted that, in the above method for preparing mask according to the embodiments of the present disclosure, the patterning process for example may merely comprise lithographic process; or alternatively, it may for example comprise both lithographic process and etching process and for example may further comprise other processes for forming preset patterns, such as printing, ink-jet printing or the like. The lithographic process refers to a plurality of specific processes for forming patterns using photoresist, mask, exposing machine (the plurality of specific processes comprising processes such as film formation, exposing, developing and the like). In specific implementation, the corresponding patterning process may for example be selected for example depending on the structure formed in the embodiments of the present disclosure.

Since the method for preparing the mask follows the same principle as the above mask so as to solve the above described problem, then the embodiments for the method for preparing the mask may refer to the implementations for the mask as mentioned above, without repeating the details any more.

As to the above mask and the method for the mask provided in embodiments of the present disclosure, the mask comprises: a substrate; and at least a first photo-resistance structure and at least a second photo-resistance structure on the substrate; the first photo-resistance structure comprises a first light shielding film layer and an optical filter film layer, the optical filter film layer abutting against closely at least one side of the first light shielding film layer, wherein the optical filter film layer is formed to extend towards the first light shielding film layer and beyond the first light shielding film layer in the direction perpendicular to the thickness direction of the first light shielding film layer; and the second photo-resistance structure only comprises a second light shielding film layer. In summary, the technical solutions of the embodiments of the present disclosure have following advantageous effects: by providing the optical filter film layer to abut against closely at least one side of the first light shielding film layer and arranging the optical filter film layer to extend towards two opposite sides of the first light shielding film layer and beyond the first light shielding film layer in the direction perpendicular to the thickness direction of the first light shielding film layer, the quantity of exposure of light passing through the two opposite sides of the light shielding layer may be reduced so as to prevent the pattern formed by the first photo-resistance structure from being overexposed. As such, the patterns to be formed under different requirements on quantity of exposure may be formed for example by one mask having both of the first photo-resistance structure and the second photo-resistance structure, so as to simplify the manufacturing process.

It is apparent that, those skilled in the art can make various modifications and variations on embodiments of the present disclosure without departing from spirit and scope of embodiments of the present disclosure. As such, if these modifications and variations of these embodiments of the present disclosure belong to scope of the claims and equivalent of the present disclosure, then, embodiments of the present disclosure may also be intended to comprise these modifications and variations therein.

1. A mask, comprising:
a substrate; and
at least one first photo-resistance structure and at least one second photo-resistance structure on the substrate;
wherein the first photo-resistance structure comprises a first light shielding film layer and an optical filter film layer, and the optical filter film layer comprises a first optical filter portion whose orthographic projection on the substrate is located out of an edge of an orthographic projection of the first light shielding film layer on the substrate and adjoins the edge of the orthographic projection of the first light shielding film layer on the substrate; and
the second photo-resistance structure comprises a second light shielding film layer.

2. The mask according to claim 1, wherein the first optical filter portion is arranged to adjoin the first light shielding film layer in a thickness direction of the first light shielding film layer or in a direction perpendicular to the thickness direction of the first light shielding film layer.

3. The mask according to claim 1, wherein the orthographic projection of the first light shielding film layer on the substrate is surrounded by or contained within the orthographic projection of the optical filter film layer on the substrate.

4. The mask according to claim 3, wherein the optical filter film layer is located between the substrate and the first light shielding film layer.

5. The mask according to claim 3, wherein the optical filter film layer further comprises:
a second optical filter portion on a side of the first light shielding film layer which side faces away from the substrate.

6. The mask according to claim 1, wherein the first photo-resistance structure is configured to form metal lines therein and the second photo-resistance structure is configured to form channels therein.

7. The mask according to claim 1, wherein both the material by which the first light shielding film layer is formed and the material by which the second light shielding film layer is formed comprise a material composition of chromium molybdenum oxide.

8. A method for preparing a mask, the method comprising:
forming a pattern of a first photo-resistance structure and a pattern of a second photo-resistance structure on a substrate;
wherein the first photo-resistance structure comprises a first light shielding film layer and an optical filter film layer, the optical filter film layer comprises a first optical filter portion whose orthographic projection on the substrate is located out of an edge of an orthographic projection of the first light shielding film layer on the substrate and adjoins the edge of the orthographic projection of the first light shielding film layer on the substrate; and
the second photo-resistance structure comprises a second light shielding film layer.

9. The method according to claim 8, wherein the forming the pattern of the first photo-resistance structure and the pattern of the second photo-resistance structure on the substrate comprises:
forming a pattern of the first light shielding film layer and a pattern of the second light shielding film layer on the substrate by using one patterning process; and
forming a pattern of the optical filter film layer on the substrate by using another patterning process,
wherein a pattern of the first optical filter portion of the optical filter film layer adjoins the first light shielding film layer in thickness direction of the first light shielding film layer or in a direction perpendicular to the thickness direction of the first light shielding film layer.

10. The method according to claim 8, wherein the orthographic projection of the first light shielding film layer on the substrate is surrounded by or contained within the orthographic projection of the optical filter film layer on the substrate.

11. The method according to claim 8, wherein the forming the pattern of the first photo-resistance structure and the pattern of the second photo-resistance structure on the substrate comprises:
forming a pattern of the first light shielding film layer and a pattern of the second light shielding film layer on the substrate by using one patterning process; and
forming a pattern of the optical filter film layer on a side of the first light shielding film layer which side faces away from the substrate by using another patterning process,
wherein the pattern of the optical filter film layer further comprises:
a second optical filter portion covering a side of the first light shielding film layer which side faces away from the substrate.

12. The method according to claim 8, wherein the forming the pattern of the first photo-resistance structure and the pattern of the second photo-resistance structure on the substrate comprises:
forming a pattern of the optical filter film layer on the substrate by using one patterning process; and
forming a pattern of the first light shielding film layer on a side of the optical filter film layer which side faces away from the substrate, while forming a pattern of the second light shielding film layer on a portion of the substrate which portion is not covered by the optical filter film layer, by using another patterning process.

13. The method according to claim 8, wherein the first photo-resistance structure is configured to form metal lines therein, and the second photo-resistance structure is configured to form channels therein.

14. The method according to claim 8, wherein both the material by which the first light shielding film layer is formed and the material by which the second light shielding film layer is formed comprise a material composition of chromium molybdenum oxide.

15. The mask according to claim 2, wherein both the material by which the first light shielding film layer is formed and the material by which the second light shielding film layer is formed comprise a material composition of chromium molybdenum oxide.

16. The mask according to claim 3, wherein both the material by which the first light shielding film layer is formed and the material by which the second light shielding film layer is formed comprise a material composition of chromium molybdenum oxide.

17. The method according to claim 9, wherein both the material by which the first light shielding film layer is formed and the material by which the second light shielding film layer is formed comprise a material composition of chromium molybdenum oxide.

18. The method according to claim 10, wherein both the material by which the first light shielding film layer is formed and the material by which the second light shielding film layer is formed comprise a material composition of chromium molybdenum oxide.

19. The method according to claim 11, wherein both the material by which the first light shielding film layer is formed and the material by which the second light shielding film layer is formed comprise a material composition of chromium molybdenum oxide.

20. The method according to claim 12, wherein both the material by which the first light shielding film layer is formed and the material by which the second light shielding film layer is formed comprise a material composition of chromium molybdenum oxide.
